(19) United States
(12) Patent Application Publication
(10) Pub. No.: US 2015/0357554 A1
(43) Pub. Date: Dec. 10, 2015

(54) METHOD FOR PRODUCING A MULTILAYER DIELECTRIC POLYURETHANE FILM SYSTEM

(71) Applicant: Bayer MaterialScience AG, Leverkusen (DE)

(72) Inventors: Jens KRAUSE, Leverkusen (DE); Joachim WAGNER, Köln (DE)

(21) Appl. No.: 14/412,283

(22) PCT Filed: Jul. 1, 2013
(86) PCT No.: PCT/EP2013/063852

§ 371 Date: Dec. 31, 2014

(30) Foreign Application Priority Data
Jul. 3, 2012 (EP) 12174858.6

(51) Int. Cl. H01L 41/27; C09D 175/04; H01L 41/193; H01L 41/317; H01L 41/45

(52) U.S. Cl. CPC H01L 41/27; H01L 41/317; H01L 41/45; H01L 41/193; C09D 175/04

(57) ABSTRACT

The present invention relates to a method for producing a multilayer dielectric polyurethane film system comprising the following method steps: I) producing a mixture comprising a) a compound containing isocyanate groups with an isocyanate group content of >10% by weight and ≦50% by weight, b) a compound containing isocyanate reactive groups with an OH number of ≧20 and ≦150, wherein the sum of the number average functionality of isocyanate groups and of isocyanate reactive groups in compounds a) and b) is ≧2.6 and ≦6, II) applying the mixture immediately after it has been produced to a substrate in the form of a wet film, III) curing said wet film while forming the polyurethane film and IV) applying an electrode layer on the almost completely dried film, V) repeating steps I)-IV) to generate a multilayer system. The invention further relates to a multilayer dielectric polyurethane film system and an electromechanical transducer.

The present invention relates to a process for producing a multilayer electroactive polymer film system from layers of dielectric polyurethane and conductive electrode layer having a structure, in an alternating construction (multilayer actuator), which is especially suitable for use in electromechanical transducers. The invention further provides a dielectric polyurethane film system obtainable by the process according to the invention and an electromechanical transducer obtainable by this process.

Transducers—also called electromechanical transducers—convert electrical to mechanical energy and vice versa. They can be used as a constituent of sensors, actuators and/or generators.

The basic construction of such a transducer consists of electroactive polymers (EAP). The principle of construction and the mode of action are similar to those of an electrical capacitor. A dielectric is present between two conductive plates to which a voltage is applied. However, EAPs are an extensible dielectric which deforms in the electrical field. More specifically, they are dielectric elastomers, usually in the form of films (DEAP; dielectric electroactive polymer), which have high electrical resistivity and are coated on both sides by extensible electrodes having high conductivity (electrode), as described, for example, in WO-A 01/006575. This basic construction can be used in a wide variety of different configurations for production of sensors, actuators or generators. As well as single-layer constructions, multilayer constructions are also known.

Electroactive polymers as elastic dielectric in transducer systems must have different properties in different components according to the application: actuators/sensors or generators.

Shared electrical properties are: a high electrical internal resistance of the dielectric, a high electrical breakdown resistance and a high dielectric constant in the frequency range of the application. These properties allow long-term storage of a large amount of electrical energy in the volume filled with the electroactive polymer.

Shared mechanical properties are sufficiently high elongation at break, low persistent extension and sufficiently high compressive/tensile strengths. These properties ensure sufficiently high elastic deformability without mechanical damage to the energy transducer. For energy transducers which are operated under tension, i.e. are subjected to tensile stress in operation, it is particularly important that these elastomers have no persistent extension (“creep” should not occur, since otherwise no EAP effect is present any longer after a particular number of extension cycles) and do not exhibit any stress relaxation under mechanical load.

However, there are also different demands depending on the application: For actuators in tension mode, elastomers of highly reversible extensibility with high elongation at break and low tensile modulus of elasticity are required. For generators which are operated under strain, in contrast, a high tensile modulus of elasticity is advisable. The demands on internal resistivity are also different; for generators, much higher demands are made on internal resistivity than for actuators.

It is known from the literature for actuators that extensibility is proportional to the dielectric constant and the square of the voltage applied, and inversely proportional to the modulus.

with the relative permittivity ∈ᵣ, the stiffness Y and the film thickness d with the switching voltage, U shows the extension s₂ according to the equation

$${s}_{z} = \frac{{σ}_{Maxwell}}{Y} = \frac{{ɛ}_{0} \cdot {ɛ}_{r}}{Y} {( \frac{U}{d} )}^{2} ( with the absolute permittivity {ɛ}_{0} )$$

The voltage is in turn dependent on the dielectric strength, meaning that, if the dielectric strength is very low, a high voltage cannot be applied. Since the square of this value is present in the equation for calculation of the extension which is caused by the electrostatic attraction of the electrodes, the dielectric strength must be correspondingly high. A typical equation for this can be found in the book by Federico Carpi, Dielectric Elastomers as Electromechanical Transducers, Elsevier, page 314, equation 30.1, and similarly also in R. Pelrine, Science 287, 5454, 2000, page 837, equation 2. The equation from the above paragraph makes clear a very important property for the operation of dielectric elastomer actuators: The lower the layer thickness zo, the smaller the operating voltage of the actuators can be. At the same time, however, the deformation amplitude also falls with the layer thickness. A way out of this dilemma has already been shown by PELRINE, in an early publication from 1997 inter alia: Analogously to piezoelectric stack actuators, it is possible to stack individual layers one on top of another [R. E. PELRINE, R. KORNBLUH, J. P. JOSEPH and S. CHIBA, “Electrostriction of polymer films for microactuators”, in: Micro Electro Mechanical Systems, 1997. MEMS '97, Proceedings, IEEE., Tenth Annual International Workshop on (1997), p. 238-243]. These layers are electrically connected in parallel, meaning that there is a relatively high field strength E over each layer in spite of low operating voltage U. In mechanical terms, in contrast, the actuator layers are connected in series; the individual deformations are additive. The stack demonstrated by PELRINE et al. had four layers of dielectric and electrode and was produced manually. It is important that the electrode layers have a structure. This can be achieved through a spray mask, inkjet printing or else a screen in the case of screen printing. Since then, this idea has been taken up several times and developed further. A great challenge in the production of a stack actuator in all processes is the faultless and contamination-free stacking of a multitude of dielectric layers and electrodes. CARPI et al. identified the cutting-open of a tube as a solution to this problem. The dielectric is in the form of a silicone tube.

This tube is cut open in a spiral manner, then the cut faces are covered with conductive material, and these then serve as electrodes [F. CARPI, A. MIGLIORE, G. SERRA and D. DE ROSSI. “Helical dielectric elastomer actuators”, in: Smart Materials and Structures 14.6 (2005), p. 1210-1216. In 2007, CHUC et al. presented an automated process which in principle is based on the folding according to CARPI [N. H. CHUC, J. K. PARK, D. V. THUY, H. S. KIM, J. C. KOO et al. “Multi-stacked artificial muscle actuator based on synthetic elastomer”, in: Proceedings of the 2007 IEEE/RSJ International Conference on Intelligent Robots and Systems San Diego, Calif., USA, Oct. 29-Nov. 2, 2007 (2007), p. 771]. However, the dielectric films here are folded only once. The stack actuators of CARPI et al. and CHUC et al. are not designed to absorb tensile forces. Since the electrostatic forces reach only from the outside to the outside of adjacent electrodes, there is the risk of delamination of the stack actuators, since no forces exist within the electrodes. KOVACS and DORING developed a technique for production of extremely thin carbon black layers. Electrodes produced thereby are said to consist only of one layer of primary particles. Such a monolayer builds up electrostatic forces on both adjacent electrodes and is thus capable also of absorbing tensile forces [G. KOVACS and L. DÜRING. “Contractive tension force stack actuator based on soft dielectric EAP”, in: Electroactive Polymer Actuators and Devices (EAPAD) 2009, ed. by Y. BAR-COHEN and T. WALLMERSPERGER. Vol. 7287. 1. San Diego, Calif., USA: SPIE, 2009, 72870A-15]. A feature common to the stack actuator concepts of CARPI et al., CHUC et al. and KOVACS and DÜRING presented so far is that they are designed as actuating drives with large displacements and for the generation of high forces. Of these two basic configurations, stack actuators based on a 3D multilayer structure enable the most efficient conversion of electrical input energy to mechanical work because of the parallelism thus achieved by construction means between electrical field and direction of extension. However, the actuators now available have three main disadvantages, which are attributable to the insufficiently adapted elastomer, the inadequate pilot manufacturing technology and the inadequate long-term stability. A disadvantage of all the processes mentioned is that the layers only adhere weakly to one another and the layer composite is not of monolithic structure. Thus, it is often possible to take the layers apart after fewer than 100 stress cycles, i.e. delamination of the layers takes place. Such processes are also as yet unknown for polyurethane. The problem addressed by the invention was that of producing monolithic multi-ply layers without interfaces, such that no delamination and separation of the layers is possible.

Actuators known to date either have too low a dielectric constant and/or dielectric strength or too high a modulus. Another disadvantage of known solutions is the low electrical resistivity, which leads to high leakage currents in actuators and in the worst case to electrical breakdown. In order to achieve high displacements in actuators, these actuators must have a multilayer structure according to the equation.

For generators, it is important that they result in a high electrical current yield with low losses. Typical losses arise at interfaces, in the course of charging and discharging of the dielectric elastomer and through leakage currents resulting from the dielectric elastomer. In addition, the resistivity of the electrically conductive electrode layer of the EAP results in an energy loss; the electrode should therefore again have minimum electrical resistivity. A description can be found in an article by Christian Graf and Jürgen Maas, Energy harvesting cycles based on electro active polymers, proceedings of SPIE Smart structures, 2010, vol. 7642, 764217. It follows from the derivations according to equations 34 and 35 on page 9 (12) last sentence that the energy loss is at a minimum when the dielectric constant and the electrical resistivity are particularly high.

Since virtually all electroactive polymers are operated under cyclical stresses and with pre-extended structures, the materials, as mentioned, must not have a tendency to flow under repeated cyclical stresses, and the creep should be as low as possible.

The prior art describes transducers containing various polymers as a constituent of the electroactive layer (see, for example, in WO-A 01/006575), and processes for production thereof.

DE 10 2007 005 960 describes carbon black-filled polyether-based polyurethanes. A disadvantage of this invention is the very low electrical resistivity of the DEAP film, such that loss through heat is too high.

WO 2010/049079 describes one-component polyurethane systems in organic solvents. A disadvantage here is that only low degrees of branching can be used, and so the systems creep to much too high a degree under cyclical extension stresses. One-component polyurethane systems are possible only for linear unbranched systems having a functionality of 2 or less, and so the systems known from DE 10 2007 059 858 do not meet the demands. A one-component solution of higher functionality (in organic or aqueous solvents/dispersion) would lead to a gel or powder with infinite molar mass, which makes coating/film formation impossible. At the same time, owing to linearity, a reversible tension-elongation operation, like the one that has to be employed in the case of EAPs, is impossible since it results in creep of the polymer. Furthermore, the electrical resistivity of the polyether systems described is too low.

EP 2 280 034 describes polyether polyols having too low an electrical resistivity.

EP2330649 describes various approaches to a solution. Both the tensile strengths and the electrical resistivities, and also the dielectric strength, are too low to arrive at high efficiencies of industrial relevance.

WO 2010012389 describes amine-crosslinked isocyanates, but here too the electrical resistivity and the dielectric strength are too low.

In all the processes described in the prior art, it is disadvantageous that multilayer actuators based on polyurethane cannot be produced since the layers in separate production after a roll-to-roll process do not adhere strongly enough to one another and delaminate.

The problem addressed by the present invention was therefore that of providing a continuous process with which multilayer systems, i.e. layer systems composed of dielectric polyurethane films and electrode layers arranged in alternating sequence, can be obtained. The multilayer transducers obtainable therefrom should have a very high resilience, and also should not have a tendency to creep and have a high electrical resistivity.

More particularly, the dielectric polyurethane film systems producible by the process should have one or more of the following properties:
A): for actuators which are operated in tension mode:
a) tensile strength >2 MPa, more preferably >4, very particularly >5 to DIN 53 504
b) elongation at break >200% to DIN 53 504
c) creep at 10% deformation after 30 min to DIN 53 441<30% (more preferably <20, very particularly <10%)
   B): for all actuators:
   d) creep at 10% deformation after 30 min to DIN 53 441<30% (more preferably <20
   e) dielectric strength >40 V/μm to ASTM D 149-97a (more preferably >60, most preferably >80)
   f) electrical resistivity >1.5E12 ohm m to ASTM D 257 (more preferably >2E12 ohm m, very particularly >5 E 12 ohm m, very particularly >1E13 ohm m).
   g) permanent elongation at 50% elongation to DIN 53 504<3%
   h) dielectric constant >5 at 0.01-1 Hz to ASTM D 150-98
   i) layer thickness of a dielectric film (calculated as monolayer)<1000 μm
   j) where the system preferably consists of >50 and <10000 plies
   k) and the layers adhere indestructibly to one another.

The problem addressed by the invention is solved by a process for producing a multilayer dielectric polyurethane film system, in which at least the following steps are performed:
I) producing a mixture comprising
   a) a compound containing isocyanate groups and having a content of isocyanate groups of >10% by weight and ≦50% by weight,
   b) a compound containing isocyanate-reactive groups and having an OH number of ≧20 and ≦150,
   where the sum of the number-average functionalities of isocyanate groups and of isocyanate-reactive groups in the compounds a) and b) is ≧2.6 and ≦6,
II) applying the mixture immediately after production thereof in the form of a wet film to a carrier,
III) curing the wet film to form the polyurethane film and
IV) applying an electrode layer, especially a structured electrode layer, to the almost completely dried film, especially by spraying, casting, knife-coating, inkjet or the like, the electrode optionally comprising a binder and optionally being dried,
V) repeating steps I)-IV), preferably >2 and <1000000 times, more preferably >5 and <100000 and especially preferably >10 and <10000, very especially preferably >10 and <5000 and even more especially preferably >20 and <1000.

The multilayer film produced by the process according to the invention has good mechanical strength and high elasticity. In addition, it has good electrical properties such as a high dielectric strength, a high electrical resistivity and a high dielectric constant, and can therefore be used advantageously in an electromechanical transducer with high efficiency.

According to the invention, the layers are preferably produced by stacking, such that preferably every layer is just dry, in order to prevent the next layer from running into the lower layer, but is still tacky enough that indestructible adhesion is present, and this ideally still includes further chemical reaction. The 100% conversion of an applied layer is thus preferably only effected by the drying operations that the further layers undergo. This gives a monolithic layer structure without delamination of the layers.

The greatest advantage of the inventive chemical process is the high bonding and adhesive force of the polyurethane to the electrode layer, but in particular the monolithic structure which forms with the lower polyurethane layer, in the case of a structured electrode surface, which is smaller than the polyurethane surface.

The main disadvantage of a mechanical stacking process compared to this is that the release foil of the film always has to be removed here first, prior to the application. This results in stretching of the film, which usually develops creases or even tears, and in any case the structure changes under strain. As a result, it is mechanically impossible to join a ply exactly onto the next ply, and so, in the case of a structure with a high number of layers, there may in the worst case be such significant slippage that an electrical sparkover takes place. However, even small distortions lead to a loss in the field of influence of the actuator. It is therefore particularly disadvantageous, and in some cases even impossible, to produce small structures, and so mechanical production is only suitable for large structures. A further disadvantage is that the mechanical steps are all successive, and thus are relatively unproductive with conventional manufacturing methodology.

With the chemical process, it is possible using suitable masks not just to structure the layers in a controlled manner actually within the production process, but also to place them exactly 1:1 onto one another and to process them. The adhesion of the polyurethane (which is generally higher than silicone) is higher as a result of the chemical process. The inventive process also has merely a carrier at the lowermost ply, and so this is only removed in the last step on finalization of all layers, and hence no prior strain is present. In other words: After production of the first layer on the carrier, the optionally structured electrode layer applied to the almost completely dried film serves as the carrier for the next polyurethane film, so as to form a layer stack [PU layer-electrode]ₙ where n=2, 3, 4, . . . . In this context, individual polyurethane layers of different thickness are possible in the layer composite: [(polyurethane layer of a 1st thickness)-(electrode)]-[(polyurethane layer of a 2nd thickness)-(electrode)]-etc.

A further advantage is that the layer thicknesses which are produced can be significantly lower. This is because, in the case of the mechanical variant, the layers always have to be removed from the carrier and thus tear in the case of thin layers. This disadvantage does not exist in the process according to the invention. Productivity is much higher through the lack of robots for removal of the plies and more readily obtainable through modern carousel technology.

Suitable compounds a) in accordance with the invention are, for example, butylene 1,4-diisocyanate, hexamethylene 1,6-diisocyanate (HDI), isophorone diisocyanate (IPDI), 2,2,4- and/or 2,4,4-trimethylhexamethylene diisocyanate, the isomeric bis(4,4′-isocyanatocyclohexyl)methanes (H12-MDI) or mixtures thereof with any isomer content, cyclohexylene 1,4-diisocyanate, 4-isocyanatomethyl-1,8-octane diisocyanate (nonane triisocyanate), phenylene 1,4-diisocyanate, tolylene 2,4- and/or 2,6-diisocyanate (TDI), naphthylene 1,5-diisocyanate, diphenylmethane 2,2′- and/or 2,4′- and/or 4,4′-diisocyanate (MDI), 1,3- and/or 1,4-bis(2-isocyanatoprop-2-yl)benzene (TMXDI), 1,3-bis(isocyanatomethyl)benzene (XDI), alkyl 2,6-diisocyanatohexanoates (lysine diisocyanates) having alkyl groups having 1 to 8 carbon atoms, and mixtures thereof. In addition, compounds containing modifications such as allophanate, uretdione, urethane, isocyanurate, biuret, iminooxadiazinedione or oxadiazinetrione structure and based on said diisocyanates are suitable units for component a), as are polycyclic compounds, for example polymeric MDI (pMDI) and combinations of all of these. Preference is given to modifications having a functionality of 2 to 6, preferably of 2.0 to 4.5 and more preferably of 2.6 to 4.2 and most preferably of 2.8 to 4.0 and more preferably of 2.8 to 3.8.

Particular preference is given to modification using diisocyanates from the group of HDI, IPDI, H12-MDI, TDI and MDI. Particular preference is given to using HDI. Very particular preference is given to using a polyisocyanate based on HDI and having a functionality of >2.6. Particular preference is given to using biurets, allophanates, isocyanurates and iminooxadiazinedione or oxadiazinetrione structure, very particular preference to using biurets. The preferred NCO content is >10% by weight, more preferably >15% and most preferably >18% by weight. The NCO content is <=50% by weight, preferably <40% by weight, most preferably <35% by weight, most preferably <30% by weight and most preferably <25% by weight. The NCO content is more preferably between 18 and 25% by weight. Very particular preference is given to using, as a) modified aliphatic isocyanates based on HDI, those having a free, unreacted monomeric content of free isocyanate of <0.5% by weight.

In a preferred embodiment, the compound a) has a number-average functionality of isocyanate groups of ≧2.0 and ≦4.

It is also advantageous, more particularly, when the compound a) comprises or consists of an aliphatic polyisocyanate, preferably hexamethylene diisocyanate and more preferably a biuret and/or isocyanurate of hexamethylene diisocyanate.

According to the prior art, the isocyanate groups may also be present in partially or completely blocked form until their reaction with the isocyanate-reactive groups, and so they cannot react immediately with the isocyanate-reactive group. This ensures that the reaction does not take place until at a particular temperature (blocking temperature). Typical blocking agents can be found in the prior art and am selected such that they are eliminated again from the isocyanate group at temperatures between 60 and 220° C., according to the substance, and only then react with the isocyanate-reactive group. There are blocking agents which are incorporated into the polyurethane, and also those which remain as a solvent or plasticizer in the polyurethane or outgas from the polyurethane. Reference is also made to blocked NCO values. If the invention refers to NCO values, this is always based on the unblocked NCO value. Blocking is usually effected up to <0.5%. Typical blocking agents are, for example, caprolactam, methyl ethyl ketoxime, pyrazoles, for example 3,5-dimethyl-1,2-pyrazole or 1-pyrazole, triazoles, for example 1,2,4-triazole, diisopropylamine, diethyl malonate, diethylamine, phenol or derivatives thereof, or imidazole.

The isocyanate-reactive groups of compound b) are functional groups which can react to form covalent bonds with isocyanate groups. More particularly, these may be amine, epoxy, hydroxyl, thiol, mercapto, acryloyl, anhydride, vinyl and/or carbinol groups. More preferably, the isocyanate-reactive groups are hydroxyl and/or amine groups.

It is advantageous when the compound b) has a number-average functionality of isocyanate-reactive groups of ≧2.0 and ≦4, the isocyanate-reactive groups preferably being hydroxyl and/or amine.

The compound b) may preferably have an OH number ≧27 and ≦150 and more preferably ≧27 and ≦120 mg KOH/g.

The mean functionality of an isocyanate-reactive group in b) may be from 1.5 to 6, preferably from 1.8 to 4 and more preferably from 1.8 to 3.

The number-average molar mass of b) may be 1000-8000 g/mol, preferably 1500-4000 g/mol and more preferably 1500-3000 g/mol.

It is additionally preferable when the isocyanate-reactive group of compound b) is a polymer.

In an advantageous embodiment of the process according to the invention, the compound b) comprises or consists of a diol and more preferably a polyester diol and/or a polycarbonate diol.

In the compound b) it is possible to use polyether polyols, polyether amines, polyether ester polyols, polycarbonate polyols, polyether carbonate polyols, polyester polyols, polybutadiene derivatives, polysiloxane-based derivatives and mixtures thereof. Preferably, however, b) comprises or consists of a polyol having at least two isocyanate-reactive hydroxyl groups. Very particularly preferably, b) comprises polyether polyols, polyester polyols, polycarbonate polyols and polyether ester polyols, polybutadiene polyols, polysiloxane polyols, more preferably polybutadienols, polysiloxane polyols, polyester polyols and/or polycarbonate polyols, most preferably polyester polyols and/or polycarbonate polyols.

Suitable polyester polyols may be polycondensates of di- and optionally tri- and tetraols and di- and optionally tri- and tetracarboxylic acids or hydroxycarboxylic acids or lactones. Instead of the free polycarboxylic acids, it is also possible to use the corresponding polycarboxylic anhydrides or corresponding polycarboxylic esters of lower alcohols for preparation of the polyesters.

Polyester polyols are prepared in a manner known per so by polycondensation from aliphatic and/or aromatic polycarboxylic acids having 4 to 16 carbon atoms, optionally from the anhydrides thereof and optionally from the low molecular weight esters thereof, including cyclic esters, the reaction components used being predominantly low molecular weight polyols having 2 to 12 carbon atoms. Examples of suitable alcohols are ethylene glycol, butylene glycol, diethylene glycol, triethylene glycol, polyalkylene glycols such as polyethylene glycol, and also propane-1,2-diol, propane-1,3-diol, butane-1,3-diol, butane-1,4-diol, hexane-1,6-diol and isomers, neopentyl glycol or neopentyl glycol hydroxypivalate or mixtures thereof, preference being given to hexane-1,6-diol and isomers, butane-1,4-diol, neopentyl glycol and neopentyl glycol hydroxypivalate. In addition, it is also possible to use polyols such as trimethylolpropane, glycerol, erythritol, pentaerythritol, trimethylolbenzene or trishydroxyethyl isocyanurate or mixtures thereof. Particular preference is given to using diols, very particular preference to using butane-1,4-diol and hexane-1,6-diol, most preferably hexane-1,6-diol.

The dicarboxylic acids used may, for example, be phthalic acid, isophthalic acid, terephthaiic acid, tetrahydrophthalic acid, hexahydrophthalic acid, cyclohexanedicarboxylic acid, adipic acid, azelaic acid, sebacic acid, glutaric acid, tetrachlorophthalic acid, maleic acid, fumaric acid, itaconic acid, malonic acid, suberic acid, 2-methylsuccinic acid, 3,3-diethylglutaric acid and/or 2,2-dimethylsuccinic acid. The acid sources used may also be the corresponding anhydrides.

It is additionally also possible to use monocarboxylic acids such as benzoic acid and hexanecarboxylic acid.

Preferred acids are aliphatic or aromatic acids of the aforementioned type. Particular preference is given to adipic acid, isophthalic acid and phthalic acid, very particular preference to isophthalic acid and phthalic acid.

Hydroxycarboxylic acids which can additionally be used as reaction participants in the preparation of a polyester polyol having terminal hydroxyl groups are, for example, hydroxycaproic acid, hydroxybutyric acid, hydroxydecanoic acid or hydroxystearic acid, or mixtures thereof. Suitable lactones are caprolactone, butyrolactone or homologues or mixtures thereof. Preference is given to caprolactone.

Very particular preference is given to using polyester diols, most preferably based on reaction products of adipic acid, isophthalic acid and phthalic acid with butane-1,4-diol and hexane-1,6-diol.

As compounds b) containing isocyanate-reactive groups, it is possible to use polycarbonates having hydroxyl groups, for example polycarbonate polyols, preferably polycarbonate diols. These can be obtained by reaction of carbonic acid derivatives such as diphenyl carbonate, dimethyl carbonate or phosgene, by means of polycondensation with polyols, preferably diols.

Examples of diols suitable for this purpose are ethylene glycol, propane-1,2- and 1,3-diol, butane-1,3- and 1,4-diol, hexane-1,6-diol, octane-1,8-diol, neopentyl glycol, 1,4-bishydroxymethylcyclohexane, 2-methyl-1,3-propanediol, 2,2,4-trimethylpentane-1,3-diol, dipropylene glycol, polypropylene glycols, dibutylene glycol, polybutylene glycols, bisphenol A, 1,10-decanediol, 1,12-dodecanediol or lactone-modified diols of the aforementioned type or mixtures thereof.

The diol component preferably contains from 40 percent by weight to 100 percent by weight of hexanediol, preferably hexane-1,6-diol and/or hexanediol derivatives. Such hexanediol derivatives are based on hexanediol and may, as well as terminal OH groups, have ester or ether groups. Such derivatives are obtainable, for example, by reaction of hexanediol with excess caprolactone or by etherification of hexanediol with itself to give di- or trihexylene glycol. The amount of these and other components are selected in a known manner in the context of the present invention such that the sum does not exceed 100 percent by weight, and more particularly is 100 percent by weight.

Polycarbonates having hydroxyl groups, especially polycarbonate polyols, are preferably of linear structure. Particular preference is given to using a polycarbonate diol based on 1,6-hexanediol.

It is likewise possible, though less preferred, to use polyether polyols in b). For example, polytetramethylene glycol polyethers are suitable, as obtainable by polymerization of tetrahydrofuran by means of cationic ring opening. Polyether polyols which are likewise suitable may be the addition products of styrene oxide, ethylene oxide, propylene oxide, butylene oxide and/or epichlorohydrin onto di- or polyfunctional starter molecules. Examples of suitable starter molecules which may be used include water, butyl diglycol, glycerol, diethylene glycol, trimethyolpropane, propylene glycol, sorbitol, ethylenediamine, triethanolamine or 1,4-butanediol, or mixtures thereof.

It is also possible to use hydroxy-functional oligobutadiene, hydrogenated hydroxy-functional oligobutadiene, hydroxy-functional siloxanes, glycerol or TMP monoallyl ether, alone or in any desired mixture.

In addition, polyether polyols can be prepared by means of alkaline catalysis or by means of double metal cyanide catalysis or optionally, in the case of a stepwise reaction, by means of alkaline catalysis and double metal cyanide catalysis from a starter molecule and epoxides, preferably ethylene oxide and/or propylene oxide, and have terminal hydroxyl groups. A description of double metal cyanide catalysts (DMC catalysis) can be found, for example, in the patent specification U.S. Pat. No. 5,158,922 and the published specification EP 0 654 302 A1.

Useful starters here include the compounds which are known to those skilled in the art and have hydroxyl and/or amino groups, and also water. The functionality of the starters here is at least 2 and at most 6. It will be appreciated that it is also possible to use mixtures of several starters. Additionally usable as polyether polyols are also mixtures of two or more polyether polyols.

Suitable compounds b) are also ester diols such as α-hydroxybutyl ∈-hydroxycaproate, ω-hydroxyhexyl γ-hydroxybutyrate, β-hydroxyethyl adipate or bis(β-hydroxyethyl) terephthalate.

Moreover, it is also possible to additionally use monofunctional compounds in step I). Examples of such monofunctional compounds are ethanol, n-butanol, ethylene glycol monobutyl ether, diethylene glycol monomethyl ether, diethylene glycol monobutyl ether, propylene glycol monomethyl ether, dipropylene glycol monomethyl ether, tripropylene glycol monomethyl ether, dipropylene glycol monopropyl ether, propylene glycol monobutyl ether, dipropylene glycol monobutyl ether, tripropylene glycol monobutyl ether, 2-ethylhexanol, 1-octanol, 1-dodecanol or 1-hexadecanol or mixtures thereof.

Less preferably, it is possible in step 1) to additionally add proportions of chain extender or crosslinking agent to compound b). Preference is given here to using compounds having a functionality of 2 to 3 and a molecular weight of 62 to 500. It is possible to use aromatic or aliphatic aminic chain extenders, for example diethyltoluenediamine (DETDA), 3,3′-dichloro-4,4′-diaminodiphenylmethane (MBOCA), 3,5-diamino-4-chloroisobutyl benzoate, 4-methyl-2,6-bis(methylthio)-1,3-diaminobenzene (Ethacure 300), trimethylene glycol di-p-aminobenzoate (Polacure 740M) and 4,4′-diamino-2,2′-dichloro-5,5′-diethyldiphenylmethane (MCDEA). Particular preference is given to MBOCA and 3,5-diamino-4-chloroisobutyl benzoate. Components suitable in accordance with the invention for chain extension are organic di- or polyamines. For example, it is possible to use ethylenediamine, 1,2-diaminopropane, 1,3-diaminopropane, 1,4-diaminobutane, 1,6-diaminohexane, isophoronediamine, isomer mixture of 2,2,4- and 2,4,4-trimethylhexamethylenediamine, 2-methylpentamethylenediamine, diethylenetriamine, diaminodicyclohexylmethane or dimethylethylenediamine, or mixtures thereof.

In addition, it is also possible to use compounds which, as well as a primary amino group, also have secondary amino groups or, as well as an amino group (primary or secondary), also have OH groups. Examples thereof are primary/secondary amines, such as diethanolamine, 3-amino-1-methylaminopropane, 3-amino-1-ethylaminopropane, 3-amino-1-cyclohexylaminopropane, 3-amino-1-methylaminobutane, alkanolamines such as N-aminoethylethanolamine, ethanolamine, 3-aminopropanol, neopentanolamine. For chain termination, it is customary to use amines having a group reactive towards isocyanates, such as methylamine, ethylamine, propylamine, butylamine, octylamine, laurylamine, stearylamine, isononyloxypropylamine, dimethylamine, diethylamine, dipropylamine, dibutylamine, N-methylaminopropylamine, diethyl(methyl)aminopropylamine, morpholine, piperidine, or suitable substituted derivatives thereof, amide amines formed from diprimary amines and monocarboxylic acids, monoketime of diprimary amines, primary/tertiary amines such as N,N-dimethylaminopropylamine.

These often have a thixotropic effect on account of their high reactivity, and so the rheology is altered to such an extent that the mixture on the substrate has a higher viscosity. Examples of non-aminic chain extenders often used are 2,2′-thiodiethanol, propane-1,2-diol, propane-1,3-diol, glycerol, butane-2,3-diol, butane-1,3-diol, butane-1,4-diol, 2-methylpropane-1,3-diol, pentane-1,2-diol, pentane-1,3-diol, pentane-1,4-diol, pentane-1,5-diol, 2,2-dimethylpropane-1,3-diol, 2-methylbutane-1,4-diol, 2-methylbutane-1,3-diol, 1,1,1-trimethylolethane, 3-methylpentane-1,5-diol, 1,1,1-trimethylolpropane, hexane-1,6-diol, heptane-1,7-diol, 2-ethylhexane-1,6-diol, octane-1,8-diol, nonane-1,9-diol, decane-1,10-diol, undecane-1,11-diol, dodecane-1,12-diol, diethylene glycol, triethylene glycol, cyclohexane-1,4-diol, cyclohexane-1,3-diol and water.

More preferably, a) and b) have low contents of free water, residual acids and metal contents. The residual water content of b) is preferably <1% by weight, more preferably <0.7% by weight (based on b)). The residual acid content of b) is preferably <1% by weight, more preferably <0.7% by weight (based on B). The residual metal contents, caused, for example, by residues of catalyst constituents which are used in the preparation of the reactants, should preferably be less than 1000 ppm and further preferably be less than 500 ppm, based on a) or b).

The ratio of isocyanate-reactive groups to isocyanate groups in the mixture of step I) may be from 1:3 to 3:1, preferably from 1:1.5 to 1.5:1, more preferably from 1:1.3 to 1.3:1 and most preferably from 1:1.02 to 1:0.95.

The mixture of step I) may, as well as the compounds a) and b), additionally also comprise assistants and additives. Examples of such assistants and additives are crosslinkers, thickeners, solvents, thixotropic agents, stabilizers, antioxidants, light stabilizers, emulsifiers, surfactants, adhesives, plasticizers, hydrophobizing agents, pigments, fillers, rheology improvers, degassing and defoaming aids, wetting additives and catalysts. The mixture of step I) more preferably comprises wetting additives. Typically, the wetting additive is present in the mixture in an amount of 0.05 to 1.0% by weight. Typical wetting additives are available, for example, from Altana (Byk additives, for instance: polyester-modified polydimethylsiloxane, polyether-modified polydimethylsiloxane or acrylate copolymers, and also, for example, C6F13 fluorotelomers).

The mixture of step 1) preferably comprises fillers having a high dielectric constant. Examples thereof are ceramic fillers, especially barium titanate, titanium dioxide and piezoelectric ceramics such as quartz or lead zirconium titanate, and organic fillers, especially those having high electrical polarizability, for example phthalocyanines, poly-3-hexylthiophene. The addition of these fillers can increase the dielectric constant of the polyurethane film.

In addition, a higher dielectric constant is also attainable by the introduction of electrically conductive fillers below the percolation threshold. Examples of such substances are carbon black, graphite, graphene, fibres, single-wall or multiwall carbon nanotubes, electrically conductive polymers such as polythiophenes, polyanilines or polypyrroles, or mixtures thereof. In this context, carbon black types of particular interest are those which have surface passivation and therefore, at low concentrations below the percolation threshold, increase the dielectric constant but nevertheless do not lead to an increase in the conductivity of the polymer.

In the context of the present invention, it is possible to add additives to increase the dielectric constants and/or the electrical breakdown field strength even after filming in steps II) and III). This can be effected, for example, by generating one or more further layers or through penetration of the polyurethane film, for example by inward diffusion.

The solvents used may be aqueous and organic solvents.

It is possible with preference to use a solvent having a vapour pressure at 20° C. of >0.1 mbar and <200 mbar, preferably >0.2 mbar and <150 mbar and more preferably >0.3 mbar and <120 mbar. This solvent can especially be added to the mixture of step I). It is particularly advantageous here that the inventive films can be produced on a roll-coating system.

The polyurethane film may have a layer thickness of 0.1 μm to 1000 μm, preferably of 1 μm to 500 μm, more preferably of 5 μm to 200 μm and most preferably of 10 μm to 100 μm.

The mixture from step I) can be applied to the carrier in step II), for example, by knife-coating, painting, casting, spinning, spraying, extrusion in a batchwise operation, i.e. in a repetitive operation comprising coating steps with intervening drying steps. The mixture is preferably applied to the carrier with a coating bar (for instance a smooth coating bar, comma bar, or the like), rolling (for instance anilox rollers, engraved rollers, smooth rollers, or the like) or a die. The die may be part of a die application system. It is also possible to operate several application systems simultaneously or successively. It is also possible to apply several layers simultaneously with one application system. Preference is given to using a die and particular preference to using a residence time-optimized and/or recirculation-free die. Most preferably, the distance of the die from the carrier is less than three times the thickness of the wet film, preferably less than twice the thickness of the wet film and more preferably less than one-and-a-half times the thickness of the wet film. If, for example 150 μm of wet film are coated on (when the wet film contains 20% by weight of solvent, this therefore corresponds to 120 μm of cured film), the distance selected from the die to the carrier should be <300 μm. If the distance from the die to the carrier is selected as described above, the films can be produced using a roller coating system.

In a further preferred embodiment of the process according to the invention, a wet film having a thickness of 10 to 300 μm, preferably of 15 to 150 μm, further preferably of 20 to 120 μm and most preferably of 20 to 80 μm can be produced in step II).

It is likewise preferable when the wet film is cured in step III) by conducting it through a first drying section preferably having a temperature of ≧40° C. and ≦120° C., further preferably ≧60° C. and ≦110° C. and especially preferably ≧60° C. and ≦100° C.

The wet film after the first drying section can also additionally be conducted through a second drying section preferably having a temperature of ≧60° C. and ≦130° C., further preferably ≧80° C. and ≦120° C. and especially preferably ≧90° C. and ≦120° C.

In addition, the wet film after the second drying section can also be conducted through a third drying section preferably having a temperature of ≧110° C. and ≦180° C., further preferably ≧110° C. and ≦150° C. and especially preferably ≧110° C. and ≦140° C.

The drying can be performed by suspension or in roller dryers, as supplied on the market, for example, by Kronert, Coatema, Drytec or Polytype. Alternatively, it is possible to use infrared or UV curing/drying operations.

The typical speed with which the wet film on the carrier is conducted through the drying section(s) is >0.5 m/min and <600 m/min, more preferably >0.5 m/min and <500 m/min and more preferably >0.5 m/min and <100 m/min.

The drying section length and the air feed of the drying sections are matched to the speed. Usually, the total residence time of the wet film in the drying section(s) is ≧10 seconds and ≦60 minutes, preferably ≧30 seconds and ≦40 minutes, further preferably ≧40 seconds and ≦30 minutes and most preferably ≧40 seconds and ≦10 minutes.

The inventive dielectric polyurethane film is provided with a further conductive layer in accordance with process step IV. This can be done on one or both sides, in one layer or in several layers one on top of another, by complete coating or by coating over partial areas. The coating may be over the full area or in structured or segmented form, i.e. only in partial areas of the surface of the layer below, with a geometric structure that can be defined specifically.

Suitable carriers for the production of a polymer film from the reaction mixture are especially glass, release paper, films and plastics, from which the dielectric polyurethane film produced can be separated in a simple manner. Particular preference is given to using paper or films. Paper can be coated on one or both sides, for example with silicone or plastics. The coating and/or the film may be produced, for example, from polymers, for instance polyethylene, polypropylene, polymethylpentene, polyethylene terephthalate, polypropylene, polyethylene, polyvinyl chloride, Teflon, polystyrene, polybutadiene, polyurethane, acrylic ester-styrene-acrylonitrile, acrylonitrile/butadiene/acrylate, acrylonitrile-butadiene-styrene, acrylonitrile/chlorinated polyethylene/styrene, acrylonitrile/methyl methacrylate, butadiene rubber, butyl rubber, casein polymers, artificial horn, cellulose acetate, cellulose hydrate, cellulose nitrate, chloroprene rubber, chitin, chitosan, cycloolefin copolymers, epoxy resin, ethylene-ethyl acrylate copolymer, ethylene-propylene copolymer, ethylene-propylene-diene rubber, ethylene-vinyl acetate, fluoro rubber, urea-formaldehyde resin, isoprene rubber, lignin, melamine-formaldehyde resin, melamine/phenol-formaldehyde, methyl acrylate/butadiene/styrene, natural rubber (gum arabic), phenol-formaldehyde resin, perfluoroalkoxyalkane, polyacrylonitrile, polyamide, polybutylene succinate, polybutylene terephthalate, polycaprolactone, polycarbonate, polychlorotrifluoroethylene, polyester, polyesteramide, polyether-block-amide, polyetherimide, polyether ketones, polyether sulphone, polyhydroxyalkanoates, polyhydroxybutyrate, polyimide, polyisobutylene, polylactide (polylactic acid), polymethylmethacrylimide, polymethylene terephthalate, polymethyl methacrylate, polymethylpentene, polyoxymethylene or polyacetal, polyphenylene ether, polyphenylene sulphide, polyphthalamide, polypyrrole, polystyrene, polysulphone, polytetrafluoroethylene, polyurethane PUR, polyvinyl acetate, polyvinyl butyral, polyvinyl chloride, polyvinylidene fluoride, polyvinylpyrrolidone, silicone, styrene-acrylonitrile copolymer, styrene-butadiene rubber, styrene-butadiene-styrene, thermoplastic starch, thermoplastic polyurethane, vinyl chloride/ethylene, vinyl chloride/ethylene/methacrylate. Alternatively, these polymers can also be used directly as carrier materials and/or additionally be provided with further internal or external release agents or layers. The layers may have barrier functions or else contain conductive structures which may be able to transfer to the dielectric polyurethane film. The plastics may be axially or biaxially oriented or stretched, and be pressure- or corona-pretreated. The films may also be reinforced. Typical reinforcements are woven fabrics, for example textile, or glass fibres.

In a particularly preferred embodiment, it is possible to use a carrier made of glass, plastic or paper, and preferably made of silicone or plastic-coated paper.

After coating, the film or paper can be directly pulled off and reused. In a particular embodiment, the film can be run in a cycle and the dielectric polyurethane film, when it is pulled off, can be transferred directly to a new carrier. In a preferred embodiment, the carrier is provided with a structure. This is also referred to as embossing. The embossing is done in such a way that the structure is transferred to the dielectric polyurethane film, in such a way that the embossing is formed only in the surface of the dielectric polyurethane film. The embossing is pulled flat when the film is extended. The embossing is such that an electrode layer on the film is pulled flat in the event of extension, without any noticeable extension of this layer itself. The embossing is preferably imprinted into the carrier in a roll-to-roll process. For example, embossing is effected here by means of a roller into a cold thermoplastic, or into a hot thermoplastic by means of a cooling process. Typical embossings are described in EP 1 919 071.

The electrode layers applied in process step IV) can be applied, for example, by means of a printing process, for instance inkjet, flexographic printing, screen printing, spraying, or by means of a coating bar, die or roller, or else by means of metallization under reduced pressure. Typical materials are based on carbon or on metals, for instance silver, copper, aluminium, gold, nickel, zinc or other conductive metals and materials. The metal may be applied as a salt or as a solution, as a dispersion or emulsion, or else as a precursor. The adhesion is adjusted such that the layers in the sequence each adhere to one another.

There follows a description, by way of example, of an industrial scale process for continuous production of the inventive multilayer polyurethane film. The figures show:

FIG. 1 a schematic structure of a multilayer coating system,

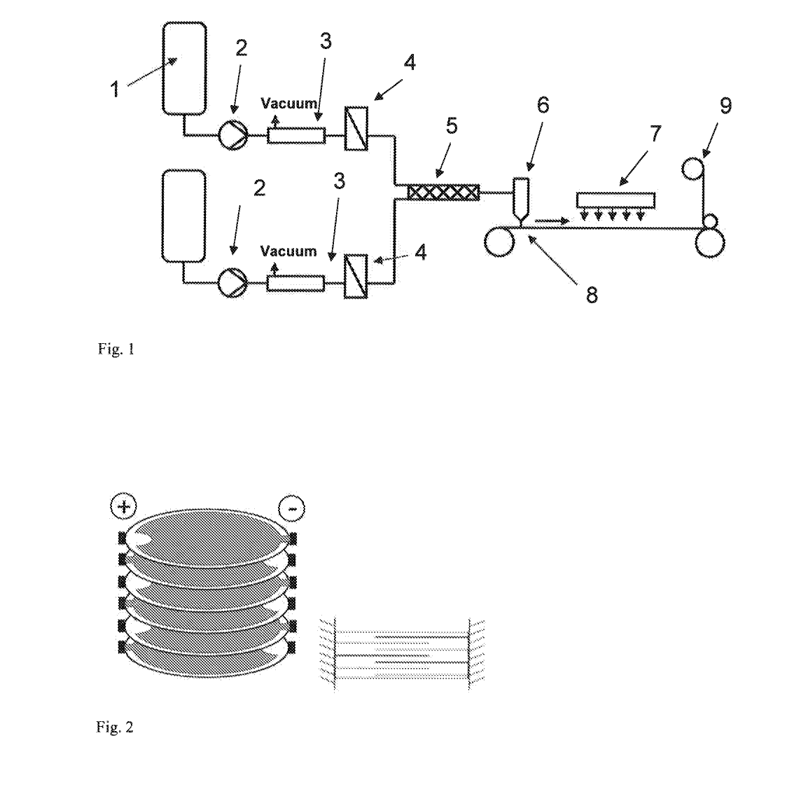

FIG. 2 an actuator with structured electrode and contacting of the layers and

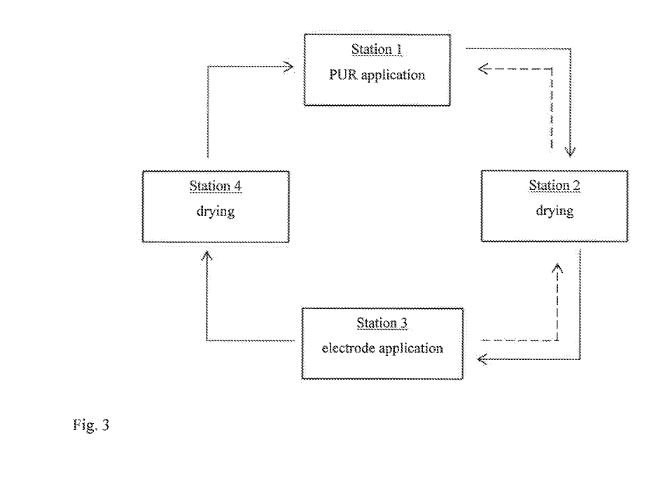

FIG. 3 a process diagram for illustration of the production process for a multilayer polyurethane layer system.

FIG. 1 shows the schematic structure of the coating system used. In the figure, the individual components have the following reference numerals:
1 reservoir vessel
2 metering device
3 vacuum degassing device
4 filter
5 static mixer
6 coating device (coating bar, inkjet printer, spray unit, or the like)
7 air circulation dryer
8 conveyor belt
9 optional covering layer

Component b) is introduced into one of the two reservoir vessels 1 of the coating system. Component a) is introduced into the second reservoir vessel 1. Each of the two components are then conveyed by the metering devices 2 to the vacuum degassing device 3, and degassed. From here, they are then each passed through the filters 4 into the static mixer 5, in which the components are mixed. The liquid material obtained is then fed to the coating device 6.

The coating device 6 in the present case is a slot die or a coating bar. With the aid of the coating device 6, the mixture is placed onto a carrier, the aforementioned mixture being applied as a wet film on a conveyor belt 8 (station 1 in FIG. 3) and then cured in an air circulation drier 7 (station 2 in FIG. 3). This gives a dielectric polyurethane film on a carrier, and this is then optionally provided with a covering layer 9 (dust reduction), which is then removed again in a subsequent step. However, the use of a covering layer 9 is not preferred. If the conveyor belt 8 is a linear conveyor belt, the sample is subsequently removed therefrom and sent to a further coating station (station 3 in FIG. 3), where the electrode layer is applied in a second step and then dried (station 4 or 2 in FIG. 3). Then the polyurethane film coated in this way is sent back to the coating unit shown in FIG. 1 (station 1 in FIG. 3) for the purpose of applying a further polyurethane layer, etc. Typical embodiments include a repetitive production system (dotted arrows in FIG. 3), such as a conveyor belt circuit or a carousel. This is a quasi-continuous process (solid arrows in FIG. 3), the intermediate layers not being isolated.

The present invention further provides a dielectric polyurethane film system produced by the process according to the invention

The invention further provides an electromechanical transducer obtainable by this process.

In the electromechanical transducer, the electrode layer is applied to the plies in such a way that it can be contacted from the sides and does not extend beyond the dielectric film edge, since sparkovers otherwise occur. Usually, a safety margin is left here between electrode and dielectric, such that the electrode area is smaller than the dielectric area. The electrode is structured such that a conductor track is led out for electrical contacting. A typical picture is suggested in FIG. 2.

The transducer can advantageously be used in a wide variety of different configurations for production of sensors, actuators and/or generators.

The present invention therefore further provides an electronic and/or electric device, especially a module, automatic device, instrument or component, comprising an inventive electromechanical transducer.

The present invention further relates to the use of an inventive electromechanical transducer in an electronic and/or electric device, especially in an actuator, sensor or generator. Advantageously, the invention can be implemented in a multitude of very different applications in the electromechanical and electroacoustic sector, especially in the sectors of energy harvesting from mechanical vibrations, acoustics, ultrasound, medical diagnostics, acoustic microscopy, mechanical sensing, especially pressure, force and/or expansion sensing, robotics and/or communications technology. Typical examples thereof are pressure sensors, electroacoustic transducers, microphones, loudspeakers, vibration transducers, light deflectors, membranes, modulators for glass fibre optics, pyroelectric detectors, capacitors and control systems and “intelligent” floors, and also systems for conversion of mechanical energy, especially from rotating or oscillating motions, to electrical energy.

### EXAMPLES

The invention is illustrated in detail hereinafter by examples.

Unless indicated otherwise, all percentages are based on weight.

Unless stated otherwise, all analytical measurements were conducted at temperatures of 23° C. under standard conditions.

### Methods:

Unless explicitly mentioned otherwise, NCO content were determined by volumetric means to DIN EN ISO 11909.

The viscosities reported were determined by means of rotary viscometry to DIN 53019 at 23° C. with a rotary viscometer from Anton Paar Germany GmbH, Germany, Helmuth-Hirth-Str. 6, 73760 Ostfildern.

Measurements of film layer thicknesses were conducted with a mechanical gauge from Dr. Johannes Heidenhain GmbH, Germany, Dr.-Johannes-Heidenhain-Str. 5, 83301 Traunreut. The specimens were analysed at three different sites and the mean was used as a representative measurement.

The tensile tests were executed by means of a tensile tester from Zwick, model number 1455, equipped with a load cell of overall measurement range 1 kN to DIN 53 504 with a pulling speed of 50 mm/min. The specimens used were S2 tensile specimens. Each measurement was executed on three specimens prepared in the same way, and the mean of the data obtained was used for assessment. Specifically for this purpose, as well as the tensile strength in [MPa] and the elongation at break in [%], the stress in [MPa] at 100% and 200% elongation was determined.

The permanent extension was determined by means of a Zwicki tensile tester from Zwick/Roell, equipped with a load cell of overall measurement range 50 N, on an S2 specimen of the sample to be examined. This measurement involved extending the sample at a rate of 50 mm/min up to n*50%, on attainment of this deformation releasing the strain on the sample to force=0 N, and measuring the extension still present. Directly thereafter, the next measurement cycle starts with n=n+1; the value of n is increased until the sample breaks. Here, only the value for 50% deformation is measured.

The determination of stress relaxation was likewise executed using the Zwick tensile tester, the instrumentation corresponds to the experiment for determination of permanent extension. The specimen used here was a sample strip of dimensions 60×10 mm², which was clamped with a clamp separation of 50 mm. After very rapid deformation to 55 mm, this deformation was kept constant for a period of 30 min and the force profile was determined over this time. The stress relaxation after 30 min is the percentage decline in stress, based on the starting value directly after deformation to 55 mm.

The measurements of dielectric constant to ASTM D 150-98 were executed with a test setup from Novocontrol Technologies GmbH & Co. KG, Obererbacher Strasse 9, 56414 Hundsangen, Germany (measurement bridge: Alpha-A Analyzer, measurement head: ZGS Active Sample Cell Test Interface) with a specimen diameter of 20 mm. A frequency range from 10⁷ Hz to 10⁻² Hz was examined. A measure used for the dielectric constant of the material examined was the real part of the dielectric constant at 10-0.01 Hz.

Electrical resistivity was measured by means of a laboratory setup from Keithley Instruments (Keithley Instruments GmbH, Landsberger StraBe 65, D-82110 Germering, Germany) model No.: 6517 A and 8009 to ASTM D 257, a method for determining the insulation resistance of materials.

The determination of dielectric strength to ASTM D 149-97a was conducted with a hypotMAX high-voltage source from Associated Research Inc, 13860 W Laurel Drive, Lake Forest, Ill. 600045-4546, USA, and a sample holder constructed in-house. The sample holder contacts the polymer samples of homogeneous thickness with only low mechanical pretension, and prevents the user from coming into contact with the voltage. The non-pretensioned polymer film in this setup is subjected to static load with rising voltage until electrical breakdown through the film occurs. The measurement result is the voltage attained at breakdown, based on the thickness of the polymer film in [V/m]. 5 measurements are executed per film and the average is reported.

To examine whether an interface layer is present, a confocal microscope (confocal laser scanning microscope, LSCM) was used. These instruments use laser light to excite fluorescent dyes, and so are fluorescence microscopes.

### Substances and Abbreviations Used:

Desmodur® N100 biuret based on hexamethylene diisocyanate, NCO content 220±0.3% (to DIN EN ISO 11 909), viscosity at 23° C. 10000±2000 mPa·s, Bayer MaterialScience AG, Leverkusen, DE
Desmodur® N75 MPA 75% Desmodur® N100 and 25% methoxypropyl acetate, 250±75 mPas, Bayer MaterialScience AG, Leverkusen, DE
P200H/DS polyester polyol based on 1,6-hexanediol and phthalic anhydride, molar mass 2000 g/mol, Bayer MaterialScience AG, Leverkusen, DE
Desmophen® C2201 polycarbonate polyol based on 1,6-hexanediol, prepared by reaction with dimethyl carbonate, molar mass 2000 g/mol, Bayer MaterialScience AG, Leverkusen, DE
Ketjenblack EC 300 J product from Akzo Nobel AG
Cabot CCI-300 (silver dispersion from Cabot)
Tib Kat 220 butyltin tris(2-ethylhexanoate), from Tib Chemicals AG, Mannheim
BYK 310 solution of a polyester-modified polydimethylsiloxane, Altana
BYK 3441 solution of an acrylate copolymer, Altana.
Methoxypropyl acetate from Sigma-Aldrich.
Hostaphan RN 2SLK: release film from Mitsubishi based on polyethylene terephthalate with silicone coating. A film of width 300 mm was used.
Baytubes® C150P: multilayer carbon nanotubes from Bayer MaterialScience AG
Release paper: polymethylpentene-coated release paper.

For the coating experiments in the Inventive Examples, a Zehntner film applicator was used for the dielectric film. The substrate was dried as follows:

A first drying section was operated at 80° C. (air feed 2 m/s), a second drying section at 100° C. (air feed 3 m/s), a third drying section at 110° C. (air feed 8 m/s), a fourth drying section at 130° C. (air feed 7, 5, 2, 2 m/s). The web speed of the carrier was regulated at 1 m/min; the air feed blown into the drying sections was dry air. The layer thickness of the finished dielectric polyurethane film was 100 m.

As a subsequent step, the electrodes was applied. For this purpose, a spray unit from Hansa (airbrush), a screen-printing system from Thieme, model 3030, an inkjet printer from Fujifilm Dimatix or a coating bar from Zehntner (ZAA 2300) was used.

### Example 1

21.39 parts by weight of Desmodur NI00 were reacted together with a polyol mixture of 0.0024 part by weight of Tib Kat 220 and 100 parts by weight of P200H/DS. The isocyanate (Desmodur N100) was used at 40° C., the polyol blend (P200H/DS with TIB Kat 220) at 80° C. The respective components were heated to 40° C. and 80° C. respectively. The static mixer was heated to 65° C.; the coating bar was at 60° C. The ratio of NCO to OH groups was 1.07. It was poured onto the Hostaphan film.

### Example 2

21.39 parts by weight of Desmodur N100 were reacted together with a polyol mixture of 0.0024 part by weight of Tib Kat 220 and 100 parts by weight of Desmophen C2201. The isocyanate (Desmodur N100) was used at 40° C., the polyol blend (Desmophen C2201 with TIB Kat 220) at 80° C. The hoses for the respective components were heated to 40° C. and 80° C. respectively. The static mixer was heated to 65° C.; the coating bar was at 60° C. The ratio of NCO to OH groups was 1.07. It was poured onto the Hostaphan film.

### Example 3

151.50 parts by weight of Desmodur N75 MPA were reacted together with a polyol mixture of 0.02 part by weight of Tib Kat 220 and 536.84 parts by weight of P200H/DS, 3.24 parts by weight of Byk 310 and 308.41 parts by weight of methoxypropyl acetate. The isocyanate (Desmodur N75 MPA) was used at 23° C., the polyol blend (P200H/DS with TIB Kat 220) at 23° C. The hoses, the static mixer and the coating bar were each at 23° C. The ratio of NCO to OH groups was 1.07. It was poured onto the paper.

### Example 4

113.62 parts by weight of Desmodur N75 BA were reacted together with a polyol mixture of 0.01 part by weight of Tib Kat 220 and 459.30 parts by weight of P200H/DS, 2.77 parts by weight of Byk 3441 and 158.31 parts by weight of butyl acetate. The isocyanate (Desmodur N75 BA) was used at 23° C., the polyol blend (P200H/DS with TIB Kat 220) at 23° C. The hoses, the static mixer and the coating bar were each at 23° C. The ratio of NCO to OH groups was 1.07. It was poured onto the paper.

### Example 5

113.62 parts by weight of Desmodur N75 BA were reacted together with a polyol mixture of 0.01 part by weight of Tib Kat 220 and 459.30 parts by weight of P200H/DS, 2.77 parts by weight of Byk 3441 and 158.31 parts by weight of butyl acetate, and also 2 parts by weight of Ketjenblack EC 300 J. The isocyanate (Desmodur N75 BA) was used at 23° C., the polyol blend (P200H/DS with TIB Kat 220) at 23° C. The hoses, the static mixer and the coating bar were each at 23° C. The layer thickness after drying was 20 μm.

### Examples 6-9

1 was provided alternately with 5, and so it was possible to produce 500 layers. The same procedure was employed with 2-4 in combination with 5.

### Example 10

4 was produced as a single layer and sprayed with Ketjenblack EC 300J. 100 μm were sprayed on. The operation was repeated 500 times. The resistance of the electrode layer was determined to be 1.89E+04 ohms.

### Example 11

4 was produced as a single layer and sprayed with Baytubes C150P. 100 μm were sprayed on. The operation was repeated 500 times. The resistance of the electrode layer was determined to be 1.54E+04 ohms.

### Example 12

4 was produced as a single layer and printed by inkjet with Cabot CCI-300. It was dried. 5 μm of electrode were applied. The operation was repeated 500 times. The resistance of the electrode layer was determined to be 1.57E+03 ohms.

### Comparative Example 1

Two polyurethane films produced according to Example 4 were used. For this purpose, two films of polyurethane were placed one on top of the other and laminated with a laminating unit having two rubber rolls under pressure 3 bar and at a speed of 5 mm/second.

It was possible to pull the layers apart again after the lamination.

### Comparative Example 2

Two polyurethane films produced according to Example 4 were used. For this purpose, two films of polyurethane were placed one on top of the other and laminated with a laminating unit having two rubber rolls under pressure 3 bar and at temperature 100° C. (roll temperature) and at a speed of 5 mm/second.

It was possible to pull the layers apart again after the lamination.

### Comparative Example 3

Two polyurethane films produced according to Example 1 were used. For this purpose, two films of polyurethane were placed one on top of the other and laminated with a laminating unit having two rubber rolls under pressure 3 bar and at temperature 100° C. (roll temperature) and at a speed of 5 mm/second.

It was possible to pull the layers apart again after the lamination.

### Comparative Example 4

Two polyurethane films produced according to Example 2 were used. For this purpose, two films of polyurethane were placed one on top of the other and laminated with a laminating unit having two rubber rolls under pressure 3 bar and at temperature 100° C. (roll temperature) and at a speed of 5 mm/second.

It was possible to pull the layers apart again after the lamination.

### Comparative Example 5

Two polyurethane films produced according to Example 3 were used. For this purpose, two films of polyurethane were placed one on top of the other and laminated with a laminating unit having two rubber rolls under pressure 3 bar and at temperature 100° C. (roll temperature) and at a speed of 5 mm/second.

It was possible to pull the layers apart again after the lamination.

### Comparative Example 6

Two polyurethane films produced according to Example 4 were used. For this purpose, two films of polyurethane were placed one on top of the other and laminated with a laminating unit having two rubber rolls under pressure 3 bar and at temperature 100° C. (roll temperature) and at a speed of 5 mm/second.

It was possible to pull the layers apart again after the lamination.

It is found that a solid layer composite is possible only through the inventive operation, by gradually crosslinking the layers chemically, one of top of another.

### Assessment of the Examples and Comparative Examples

The electrical resistivity and dielectric strength of the films were determined. The results are shown for the Comparative Examples and Inventive Examples in Table 1 below.

TABLE 1
Electrical/mechanical properties of a monolayer:

| | | Elon- | | | | | |
|---|---|---|---|---|---|---|---|
| | Tensile | gation | PE | | | DS | |
| Example | strength | at break | 50% | Creep | DC | [V/ | Rb |
| # | [MPa] | [%] | [%] | [%] | 0.01 Hz | μm] | [Ω m] |
| 1 | 7.2 | 268 | 0.75 | 4.8 | 6.7 | 110.6 | 2.82E+12 |
| 2 | 6.5 | 266 | 0.65 | 1.36 | 7.6 | 83.4 | 2.08E+12 |
| 3 | 8.9 | 305 | 0.06 | 7.97 | 5.9 | 82.5 | 2.07E+12 |
| 4 | 8.5 | 278 | 1.04 | 5.8 | 8.5 | 99.1 | 2.41E+12 |

In Example 5, the resistance was determined to be 1.10E+04, and so it is a conductive layer,

All films exhibited a very high electrical resistivity and high dielectric strength. The inventive films can especially be used for production of electromechanical transducers with particularly good efficiencies. By virtue of the 500-ply construction, it was possible to achieve 500 times the displacement. The multilayer structure did not have any adverse effects on the properties and the properties were unchanged even after several cycles, and there were no instances of delamination. The layers behaved like one layer.

1.-8. (canceled)

9. A process for producing a multilayer dielectric polyurethane film system, having the following process steps:
(I) producing a mixture comprising:
(a) a compound containing isocyanate groups and having a content of isocyanate groups of >10% by weight and ≦50% by weight,
(b) a compound containing isocyanate-reactive groups and having an OH number of ≧20 and ≦150,
wherein the sum of the number-average functionalities of isocyanate groups and of isocyanate-reactive groups in the compounds (a) and (b) is ≧2.6 and ≦6,
(II) applying the mixture immediately after production thereof in the form of a wet film to a carrier,
(III) curing the wet film to form an almost completely dried polyurethane film, and
(IV) applying an electrode layer to the almost completely dried polyurethane film,
(V) repeating steps (I)-(IV) to obtain a multilayer system.

10. The process according to claim 9, wherein the electrode layer applied in step (IV) has been structured or segmented.

11. The process according to claim 9, wherein the electrode layer is applied in step (IV) by spraying, casting, knife-coating, or inkjet.

12. The process according to claim 9, wherein the electrode layer comprises a binder.

13. The process according to claim 9, wherein the electrode layer is dried after application in step (IV).

14. The process according to claim 9, wherein steps (I) to (IV) are repeated in step (V)>2 and <1000000 times.

15. The process according to claim 14, wherein steps (I) to (IV) are repeated in step (V)>5 and <100000 times.

16. The process according to claim 15, wherein steps (I) to (IV) are repeated in step (V)>10 and <10000.

17. The process according to claim 16, wherein steps (I) to (IV) are repeated in step (V)>10 and <5000 times.

18. The process according to claim 17, wherein steps (I) to (IV) are repeated in step (V)>20 and <1000 times.

19. A multilayer dielectric polyurethane film system obtainable by a process according to claim 9.

20. An electromechanical transducer comprising a multilayer dielectric polyurethane film system according to claim 15.
